(19) United States
(12) Patent Application Publication
(10) Pub. No.: US 2025/0223683 A1
(43) Pub. Date: Jul. 10, 2025

(54) DEPOSITION MASK, DEPOSITION EQUIPMENT INCLUDING DEPOSITION MASK, METHOD OF MANUFACTURING DISPLAY DEVICE USING DEPOSITION EQUIPMENT, AND DISPLAY DEVICE MANUFACTURED BY METHOD THEREOF

(71) Applicant: Samsung Display Co., LTD., Yongin-si (KR)

(72) Inventors: Sung Woon KIM, Yongin-si (KR); Duck Jung LEE, Yongin-si (KR); Sug Woo JUNG, Yongin-si (KR)

(73) Assignee: Samsung Display Co., LTD., Yongin-si (KR)

(21) Appl. No.: 18/895,638

(22) Filed: Sep. 25, 2024

(30) Foreign Application Priority Data
Jan. 10, 2024 (KR) 10-2024-0004023

(51) Int. Cl. C23C 14/04; H10K 50/19; H10K 71/16

(52) U.S. Cl. CPC C23C 14/042; H10K 50/19; H10K 71/166

(57) ABSTRACT

A deposition mask for depositing an organic material on a first substrate includes a second substrate including a plurality of cell areas and a mask frame area defining the plurality of cell areas; and a mask membrane disposed each cell area of the second substrate. A thermal expansion coefficient of the second substrate differs by less than about 5% from a thermal expansion coefficient of the first substrate.

### CROSS-REFERENCE TO RELATED APPLICATION(S)

This application claims priority from to and benefits of Korean Patent Application No. 10-2024-0004023 under 35 U.S.C. § 119, filed on Jan. 10, 2024, in the Korean Intellectual Property Office, the entire contents which are incorporated herein by reference.

### BACKGROUND

### 1. Technical Field

Embodiments relate to a deposition mask, a deposition equipment including the deposition mask, a method of manufacturing a display device using the deposition equipment, and a display device manufactured by the method.

### 2. Description of the Related Art

A wearable device that forms a focus at a short distance from a user's eyes is being developed in the form of glasses or a helmet. For example, the wearable device may be a head mounted display (HMD) device or augmented reality (AR) glasses. Such a wearable device provides an AR screen or a virtual reality (VR) screen to a user.

A wearable device such as an HMD device or AR glasses is required to have a display specification of at least 2,000 pixels per inch (PPI) so that a user may use it for a long time without dizziness. Organic light emitting diode on silicon (OLEDoS) technology, which is a small high-resolution organic light emitting display device, is being proposed. The OLEDoS is a technology for placing an organic light emitting diode (OLED) on a semiconductor wafer substrate on which a complementary metal oxide semiconductor (CMOS) is disposed.

In order to manufacture a display panel of high-resolution of 3500 pixels per inch (PPI) or more, a high-resolution deposition mask is required.

### SUMMARY

Embodiments provide a deposition mask capable of readily manufacturing a display panel having a high resolution of 3,500 PPI or more, a deposition equipment including the deposition mask, a method of manufacturing a display device using the deposition equipment, and a display device manufactured by the method.

However, embodiments are not limited to those set forth herein. The above and other embodiments will become more apparent to one of ordinary skill in the art to which the disclosure pertains by referencing the detailed description of the disclosure given below.

According to an embodiment, a deposition mask for depositing an organic material on a first substrate may include a second substrate including a plurality of cell areas and a mask frame area defining the plurality of cell areas; and a mask membrane disposed each cell area of the second substrate. The thermal expansion coefficient of the second substrate may differ by less than about 5% from a thermal expansion coefficient of the first substrate.

The surface of the second substrate may have a roughness parameter in a range of about 20 nm or less.

The second substrate may be a substrate having a total thickness variation parameter in a range of about 100 μm or less.

The second substrate may be a substrate having a first bending parameter which indicates a degree of bending and is in a range of about 100 μm or less.

The second substrate may be a substrate having a distortion parameter, which indicates a degree of distortion and is in a range of about 100 μm or less.

The second substrate may be a substrate having a second bending parameter, which indicates a degree of bending and is in a range of about 100 μm or less.

The second substrate may be a substrate having a volume resistance in a range of about 10,000 Ohm*cm or less due to impurity doping.

The second substrate may be a silicon substrate.

A pixel pitch of the mask membrane may be in a range of about 7.2 μm or less.

A diameter of each hole included in the mask membrane may be in a range of about 5 μm or less.

A thickness of the mask membrane may be in a range of about 10 μm or less.

A critical dimension uniformity between holes included the mask membrane may be in a range of about 0.5 μm or less. A pixel position accuracy of holes included in the mask membrane may be in a range of about 0.5 μm or less.

According to an embodiment, a deposition equipment may include a chamber; a deposition source disposed in the chamber; and a mask disposed between a first substrate and the deposition source in the chamber. The mask comprises a second substrate comprising a plurality of cell areas and a mask frame defining the plurality of cell areas; and a mask membrane disposed on each cell area of the second substrate, and the thermal expansion coefficient of the second substrate may differ by less than about 5% from the thermal expansion coefficient of the first substrate.

A surface of the second substrate may have a roughness parameter in a range of about 20 nm or less.

The second substrate may be a substrate having a total thickness variation parameter in a range of about 100 μm or less.

The second substrate may be a substrate having a first bending parameter which indicates a degree of bending and is in a range of about 100 μm or less.

The second substrate may be a substrate having a distortion parameterWARP, which indicates a degree of distortion and is in a range of about 100 μm or less.

The second substrate may be a substrate having a second bending parameter, which indicates a degree of bending and is in a range of about 100 μm or less.

The second substrate may be a substrate having a volume resistance in a range of about 10,000 Ohm*cm or less due to impurity doping.

According to an embodiment, a method of manufacturing a display device may include disposing a first substrate on a surface of a mask in a chamber of a deposition equipment; disposing a deposition source to face another surface of the first substrate; and vaporizing a deposition material contained in the deposition source such that the vaporized deposition material passes through the mask to be deposited to the first substrate. The mask may include a second substrate including a plurality of cell areas and a mask frame area defining the plurality of cell areas; and a mask membrane disposed on each cell area of the second substrate, and the thermal expansion coefficient of the second substrate may differ by less than about 5% from the thermal expansion coefficient of the first substrate.

The surface of the second substrate has a roughness parameter in a range of about 20 nm or less.

The second substrate may be a substrate a total thickness variation parameter and is in a range of about 100 μm or less.

The second substrate may be a substrate having a first bending parameter, which indicates a degree of bending and is in a range of about 100 μm or less.

According to a deposition mask, a deposition equipment including the deposition mask, a method of manufacturing a display device using the deposition equipment, and a display device manufactured by the method according to embodiments, a display panel of high resolution of 3500 PPI or more may be manufactured readily.

According to a display device according to embodiments, by including a display panel of high resolution of 3,500 PPI or more, high quality of image may be proved to users.

### BRIEF DESCRIPTION OF THE DRAWINGS

The above and other aspects and features of the disclosure will become more apparent by describing in detail embodiments thereof with reference to the attached drawings, in which:

FIG. 1 is an exploded schematic perspective view showing a display device according to an embodiment;

FIG. 2 is a schematic block diagram illustrating a display device according to an embodiment;

FIG. 3 is a schematic diagram of an equivalent circuit of a first sub-pixel according to an embodiment;

FIG. 4 is a layout diagram illustrating an example of a display panel according to an embodiment;

FIGS. 5 and 6 are layout diagrams illustrating embodiments of the display area of FIG. 4;

FIG. 7 is a schematic cross-sectional view illustrating an example of a display panel taken along line I1-I1′ of FIG. 5;

FIG. 8 is a schematic perspective view illustrating a head mounted display according to an embodiment;

FIG. 9 is an exploded schematic perspective view illustrating an example of the head mounted display of FIG. 8;

FIG. 10 is a schematic perspective view illustrating a head mounted display according to an embodiment;

FIG. 11 is a schematic perspective view of a mask according to an embodiment;

FIG. 12 is a schematic plan view of the mask according to an embodiment;

FIG. 13 is a flowchart for illustrating a method of manufacturing a mask according to an embodiment;

FIGS. 14 to 18 are schematic cross-sectional views for illustrating processing steps of the method of manufacturing a mask according to an embodiment;

FIG. 19 is a flowchart for illustrating a method of manufacturing a mask according to an embodiment;

FIGS. 20 to 24 are schematic cross-sectional views for illustrating processing steps of the method of manufacturing a mask according to an embodiment;

FIG. 25 is a drawing for illustrating total thickness variation which is a total thickness variation parameter (TTV);

FIG. 26 is a drawing for illustrating a first bending parameter (BOW) which is a parameter which is a parameter indicating a degree of bending;

FIG. 27 is a drawing for illustrating a distortion parameter (WARP) indicating a degree of distortion;

FIG. 28 is a drawing for illustrating a thermal expansion coefficient (CTE); and

FIG. 29 is a schematic view showing a configuration of a deposition equipment according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, specific embodiments will be described with reference to the accompanying drawings.

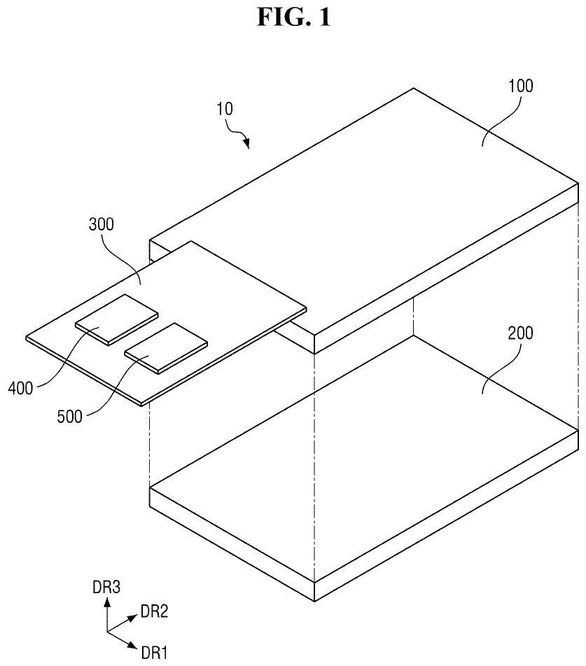

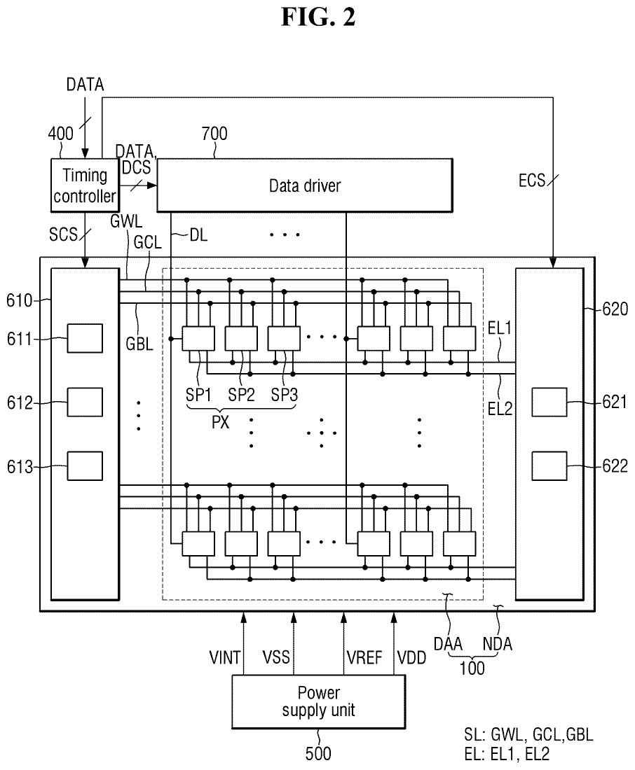

FIG. 1 is an exploded schematic perspective view showing a display device according to an embodiment. FIG. 2 is a schematic block diagram illustrating a display device according to an embodiment.

Referring to FIGS. 1 and 2, a display device 10 according to an embodiment may be a device displaying a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 according to an embodiment may be applied as a display unit of a television, a laptop, a monitor, a billboard, or an Internet-of-Things (IoT) terminal. In another example, the display device 10 according to an embodiment may be applied to a smart watch, a watch phone, a head mounted display (HMD) for implementing virtual reality and augmented reality, and the like.

The display device 10 according to an embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a selected curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but embodiments are not limited thereto.

The display panel 100 may include a display area DAA that displays an image and a non-display area NDA that does not display an image as shown in FIG. 2.

The display area DAA may include pixels PX, scan lines SL, emission control lines EL, and data lines DL.

The pixels PX may be arranged in a matrix form in the first direction DR1 and the second direction DR2. The scan lines SL and the emission control lines EL may extend in the first direction DR1, while being disposed in the second direction DR2. The data lines DL may extend in the second direction DR2, while being disposed in the first direction DR1.

The scan lines SL may include write scan lines GWL, control scan lines GCL, and bias scan lines GBL. The emission control lines EL may include first emission control lines EL1 and second emission control lines EL2.

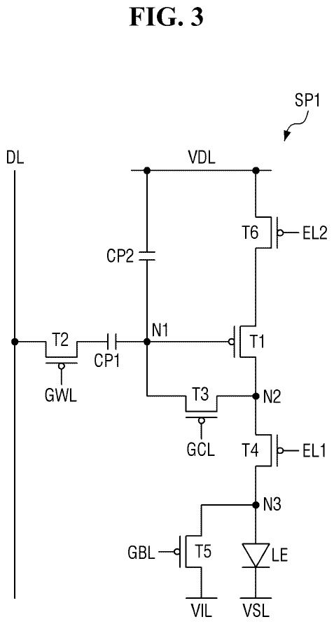

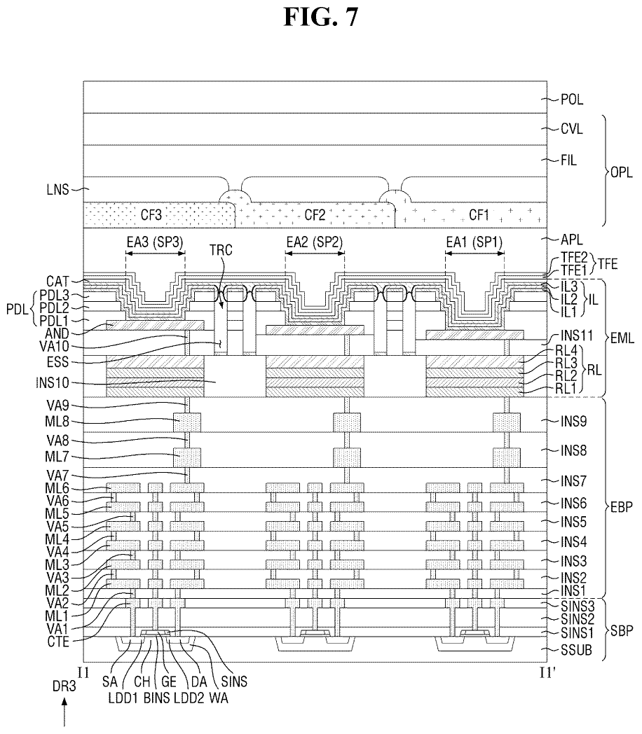

The pixels PX may include sub-pixels SP1, SP2, and SP3. The sub-pixels SP1, SP2, and SP3 may include pixel transistors as shown in FIG. 3, and the pixel transistors may be formed by a semiconductor process and disposed on a semiconductor substrate SSUB (see FIG. 7). For example, the pixel transistors of a data driver 700 may be formed using a complementary metal oxide semiconductor (CMOS).

Each of the sub-pixels SP1, SP2, and SP3 may be connected to any one write scan line GWL among the write scan lines GWL, any one control scan line GCL among the control scan lines GCL, any one bias scan line GBL among the bias scan lines GBL, any one first emission control line EL1 among the first emission control lines EL1, any one second emission control line EL2 among the second emission control lines EL2, and any one data line DL among the data lines DL. Each of the sub-pixels SP1, SP2, and SP3 may receive a data voltage of the data line DL in response to a write scan signal of the write scan line GWL, and emit light from the light emitting element according to the data voltage.

The non-display area NDA may include a scan driver 610, an emission driver 620, and the data driver 700.

The scan driver 610 may include scan transistors, and the emission driver 620 may include light emitting transistors. The scan transistors and the light emitting transistors may be formed on the semiconductor substrate SSUB (see FIG. 7) by a semiconductor process. For example, the scan transistors and the light emitting transistors may be formed using a complementary metal oxide semiconductor (CMOS). Although it is illustrated in FIG. 2 that the scan driver 610 is disposed on the left side of the display area DAA and the emission driver 620 is disposed on the right side of the display area DAA, embodiments are not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 may include a first emission control driver 621 and a second emission control driver 622. Each of the first emission control driver 621 and the second emission control driver 622 may receive the emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include data transistors, and the data transistors may be formed on the semiconductor substrate SSUB (see FIG. 7) by a semiconductor process. For example, the data transistors may be formed using a complementary metal oxide semiconductor (CMOS).

The data driver 700 may receive digital video data DATA and a data timing control signal DCS from the timing control circuit 400. The data driver 700 may convert the digital video data DATA into analog data voltages according to the data timing control signal DCS and may output the analog data voltages to the data lines DL. For example, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on a surface of the display panel 100, for example, on the rear surface thereof. The heat dissipation layer 200 may function to dissipate heat generated from the display panel 100. The heat dissipation layer 200 may include a metal layer such as graphite, silver (Ag), copper (Cu), or aluminum (Al) having high thermal conductivity.

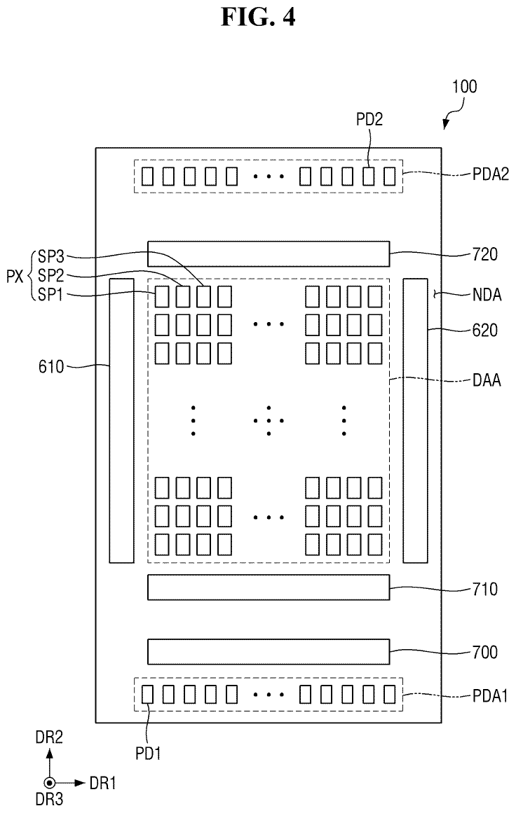

The circuit board 300 may be electrically connected to first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. For example, an end portion of the circuit board 300 may be disposed on the rear surface of the display panel 100 and/or the rear surface of the heat dissipation layer 200. An end portion of the circuit board 300 may be an opposite end portion of another end portion of the circuit board 300 connected to the first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate panel driving voltages according to a power voltage from the outside. For example, the power supply circuit 500 may generate a first driving voltage VSS, a second driving voltage VDD, a third driving voltage VINT, and a reference voltage VREF and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to a surface of the circuit board 300. For example, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, the third driving voltage VINT, and the reference voltage VREF of the power supply circuit 500 may be supplied to the display panel 100 through the circuit board 300.

In another example, each of the timing control circuit 400 and the power supply circuit 500 may be disposed in the non-display area NDA of the display panel 100, similarly to the scan driver 610, the emission driver 620, and the data driver 700. For example, the timing control circuit 400 may include timing transistors, and each power supply circuit 500 may include power transistors. The timing transistors and the power transistors may be formed on the semiconductor substrate SSUB (see FIG. 7) by a semiconductor process. For example, the timing transistors and the power transistors may be formed using a complementary metal oxide semiconductor (CMOS). Each of the timing control circuit 400 and the power supply circuit 500 may be disposed between the data driver 700 and the first pad portion PDA1 (see FIG. 4).

FIG. 3 is a schematic diagram of an equivalent circuit of a first sub-pixel according to an embodiment.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. For example, the first driving voltage VSS may be lower than the third driving voltage VINT. The second driving voltage VDD may be higher than the third driving voltage VINT.

The first sub-pixel SP1 may include transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE may be proportional to the driving current Ids. The light emitting element LE may be disposed between the fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but embodiments are not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 may include a gate electrode connected to a first node N1, a source electrode connected to the drain electrode of the sixth transistor T6, and a drain electrode connected to a second node N2.

The second transistor T2 may be disposed between an electrode of the first capacitor CP1 and the data line DL. The second transistor T2 may be turned on by the write scan signal of the write scan line GWL to connect the electrode of the first capacitor CP1 to the data line DL. Accordingly, the data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

The third transistor T3 may be disposed between the first node N1 and the second node N2. The third transistor T3 may be turned on by the write control signal of the control scan line GCL to connect the first node N1 to the second node N2. For this reason, since the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be formed between the first node N1 and the drain electrode of the second transistor T2. The first capacitor CP1 may include an electrode connected to the drain electrode of the second transistor T2 and another electrode connected to the first node N1.

The second capacitor CP2 may be formed between the gate electrode of the first transistor T1 and the second driving voltage line VDL. The second capacitor CP2 may include an electrode connected to the gate electrode of the first transistor T1 and another electrode connected to the second driving voltage line VDL.

The first node N1 may be a junction between the gate electrode of the first transistor T1, the drain electrode of the third transistor T3, another electrode of the first capacitor CP1, and the electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but embodiments are not limited thereto. Each of the first to sixth transistors T1 to T6 may be an N-type MOSFET. In another example, some of the first to sixth transistors T1 to T6 may be P-type MOSFETs, and each of the remaining transistors may be an N-type MOSFET.

Although it is illustrated in FIG. 3 that the first sub-pixel SP1 may include six transistors T1 to T6 and two capacitors CP1 and CP2, it should be noted that the equivalent circuit of the first sub-pixel SP1 is not limited to that shown in FIG. 3. For example, the number of transistors and the number of capacitors of the first sub-pixel SP1 are not limited to those shown in FIG. 3.

Further, the equivalent circuit of the second sub-pixel SP2 and the equivalent circuit of the third sub-pixel SP3 may be substantially the same as the equivalent circuit of the first sub-pixel SP1 described in conjunction with FIG. 3. Therefore, the description of the equivalent circuit of the second sub-pixel SP2 and the equivalent circuit of the third sub-pixel SP3 is omitted in the description.

FIG. 4 is a layout diagram illustrating an example of a display panel according to an embodiment.

Referring to FIG. 4, the display area DAA of the display panel 100 according to an embodiment may include the pixels PX arranged in a matrix form. The non-display area NDA of the display panel 100 according to an embodiment may include the scan driver 610, the emission driver 620, the data driver 700, a first distribution circuit 710, a second distribution circuit 720, a first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on a side of the display area DAA in the first direction DR1, and the emission driver 620 may be disposed on another side of the display area DAA in the first direction DR1. For example, the scan driver 610 may be disposed on the left side of the display area DAA, and the emission driver 620 may be disposed on the right side of the display area DAA. However, embodiments are not limited thereto, and the scan driver 610 and the emission driver 620 may be disposed on both the first side and the second side of the display area DAA.

The first pad portion PDA1 may include the first pads PD1 connected to pads or bumps of the circuit board 300 through a conductive adhesive member. The first pad portion PDA1 may be disposed on the third side of the display area DAA. For example, the first pad portion PDA1 may be disposed on a side of the display area DAA in the second direction DR2.

The first pad portion PDA1 may be disposed outside the data driver 700 in the second direction DR2. For example, the first pad portion PDA1 may be disposed closer to the edge portion of the display panel 100 than the data driver 700.

The second pad portion PDA2 may include second pads PD2 corresponding to inspection pads that test whether the display panel 100 operates normally. The second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 may distribute data voltages applied through the first pad portion PDA1 to the data lines DL. For example, the first distribution circuit 710 may distribute the data voltages applied through a first pad PD1 of the first pad portion PDA1 to the P data lines DL (P is a positive integer of 2 or more), and as a result, the number of the first pads PD1 may be reduced. The first distribution circuit 710 may be disposed on the third side of the display area DAA of the display panel 100. For example, the first distribution circuit 710 may be disposed on a side of the display area DAA in the second direction DR2. For example, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may inspect the operation of each of the pixels PX in the display area DAA. The second distribution circuit 720 may be disposed on the fourth side of the display area DAA of the display panel 100. For example, the second distribution circuit 720 may be disposed on another side of the display area DAA in the second direction DR2. For example, the second distribution circuit 720 may be disposed on the upper side of the display area DAA.

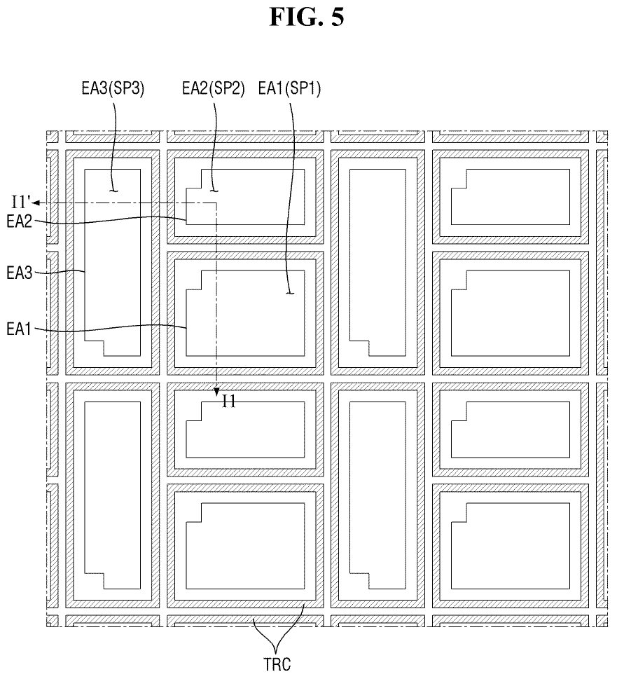

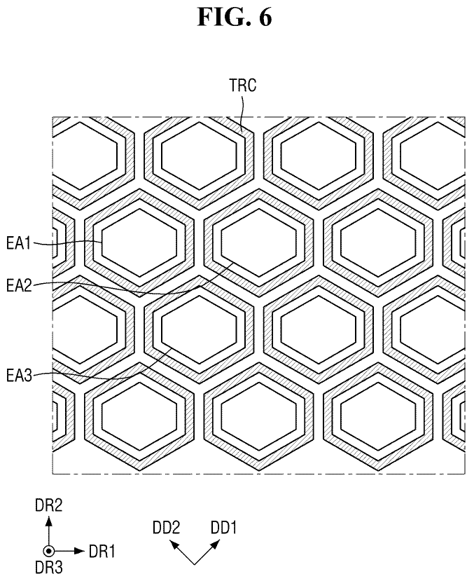

FIGS. 5 and 6 are layout diagrams illustrating embodiments of the display area of FIG. 4.

Referring to FIGS. 5 and 6, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in plan view.

The maximum length of the first emission area EA1 in the first direction DR1 may be smaller than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same as each other.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

The first emission area EA1, the second emission area EA2, and the third emission area EA3 may have, in plan view, a hexagonal shape formed of six straight lines as shown in FIGS. 5 and 6, but embodiments are not limited thereto. The first emission area EA1, the second emission area EA2, and the third emission area EA3 may have a polygonal shape other than a hexagon, a circular shape, an elliptical shape, or an atypical shape in plan view.

As shown in FIG. 5, in each of the pixels PX, the first emission area EA1 and the second emission area EA2 may be adjacent to each other in the first direction DR1. Further, the first emission area EA1 and the third emission area EA3 may be adjacent to each other in the first direction DR1. For example, the second emission area EA2 and the third emission area EA3 may be adjacent to each other in the second direction DR2. The area of the first emission area EA1, the area of the second emission area EA2, and the area of the third emission area EA3 may be different.

In another example, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by about 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. For example, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

Referring to FIGS. 5 and 6, each of the pixels PX may include three emission areas EA1, EA2, and EA3, but embodiments are not limited thereto. For example, each of the pixels PX may include four emission areas.

For example, the layout of the emission areas of the pixels PX is not limited to that illustrated in FIGS. 5 and 6. For example, the emission areas EA1, EA2, and EA3 of the pixels PX may be disposed in a stripe structure in which the emission areas are arranged in the first direction DR1, a PenTile® structure in which the emission areas are arranged in a diamond shape, or a hexagonal structure in which the emission areas having, in plan view, a hexagonal shape are arranged side by side as shown in FIG. 6.

FIG. 7 is a schematic cross-sectional view illustrating an example of a display panel 100 taken along line I1-I1′ of FIG. 5.

Referring to FIG. 7, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include the semiconductor substrate SSUB including pixel transistors PTR, semiconductor insulating layers covering the pixel transistors PTR, and contact terminals CTE electrically connected to the pixel transistors PTR, respectively. The pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. Well regions WA may be disposed on the top surface of the semiconductor substrate SSUB. The well regions WA may be regions doped with a second type impurity. The second type impurity may be different from the aforementioned first type impurity. For example, in case that the first type impurity is a p-type impurity, the second type impurity may be an n-type impurity. In another example, in case that the first type impurity is an n-type impurity, the second type impurity may be a p-type impurity.

Each of the well regions WA may include a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on a side of the gate electrode GE, and the drain region DA may be disposed on another side of the gate electrode GE.

Each of the well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that is caused by a short channel may be prevented.

A first semiconductor insulating layer SINS1 may be disposed on the semiconductor substrate SSUB. The first semiconductor insulating layer SINS1 may be formed of silicon carbonitride (SiCN) or a silicon oxide (SiOₓ)-based inorganic layer, but embodiments are not limited thereto.

A second semiconductor insulating layer SINS2 may be disposed on the first semiconductor insulating layer SINS1. The second semiconductor insulating layer SINS2 may be formed of a silicon oxide (SiOₓ)-based inorganic layer, but embodiments are not limited thereto.

The contact terminals CTE may be disposed on the second semiconductor insulating layer SINS2. Each of the contact terminals CTE may be connected to any one of the gate electrode GE, the source region SA, and the drain region DA of each of the pixel transistors PTR through holes penetrating the first semiconductor insulating layer SINS1 and the second semiconductor insulating layer SINS2. The contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be disposed on a side surface of each of the contact terminals CTE. The top surface of each of the contact terminals CTE may be exposed without being covered by the third semiconductor insulating layer SINS3. The third semiconductor insulating layer SINS3 may be formed of a silicon oxide (SiOₓ)-based inorganic layer, but embodiments are not limited thereto.

The semiconductor substrate SSUB may be replaced with a glass substrate or a polymer resin substrate such as polyimide. For example, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP may include conductive layers ML1 to ML8, vias VA1 to VA9, and insulating layers INS1 to INS9. For example, the light emitting element backplane EBP may include insulating layers INS1 to INS11 disposed between the first to eighth conductive layers ML1 to ML8.

The first to eighth conductive layers ML1 to ML8 may function to connect the contact terminals CTE exposed from the semiconductor backplane SBP to thereby implement the circuit of the first sub-pixel SP1 shown in FIG. 4. For example, the first to sixth transistors T1 to T6 may be formed on the semiconductor backplane SBP, and the connection of the first to sixth transistors T1 to T6 and the first and second capacitors CP1 and CP2 may be formed through the first to eighth conductive layers ML1 to ML8. For example, the connection between the drain region corresponding to the drain electrode of the fourth transistor T4, the source region corresponding to the source electrode of the fifth transistor T5, and the first electrode of the light emitting element LE may be also formed through the first to eighth conductive layers ML1 to ML8.

The first insulating layer INS1 may be disposed on the semiconductor backplane SBP. Each of the first vias VA1 may penetrate the first insulating layer INS1 to be connected to the contact terminal CTE exposed from the semiconductor backplane SBP. Each of the first conductive layers ML1 may be disposed on the first insulating layer INS1 and may be connected to the first via VA1.

The second insulating layer INS2 may be disposed on the first insulating layer INS1 and the first conductive layers ML1. Each of the second vias VA2 may penetrate the second insulating layer INS2 and may be connected to the exposed first conductive layer ML1. Each of the second conductive layers ML2 may be disposed on the second insulating layer INS2 and may be connected to the second via VA2.

The third insulating layer INS3 may be disposed on the second insulating layer INS2 and the second conductive layers ML2. Each of the third vias VA3 may penetrate the third insulating layer INS3 and may be connected to the exposed second conductive layer ML2. Each of the third conductive layers ML3 may be disposed on the third insulating layer INS3 and may be connected to the third via VA3.

A fourth insulating layer INS4 may be disposed on the third insulating layer INS3 and the third conductive layers ML3. Each of the fourth vias VA4 may penetrate the fourth insulating layer INS4 and may be connected to the exposed third conductive layer ML3. Each of the fourth conductive layers ML4 may be disposed on the fourth insulating layer INS4 and may be connected to the fourth via VA4.

A fifth insulating layer INS5 may be disposed on the fourth insulating layer INS4 and the fourth conductive layers ML4. Each of the fifth vias VA5 may penetrate the fifth insulating layer INS5 and may be connected to the exposed fourth conductive layer ML4. Each of the fifth conductive layers ML5 may be disposed on the fifth insulating layer INS5 and may be connected to the fifth via VA5.

A sixth insulating layer INS6 may be disposed on the fifth insulating layer INS5 and the fifth conductive layers ML5. Each of the sixth vias VA6 may penetrate the sixth insulating layer INS6 and may be connected to the exposed fifth conductive layer ML5. Each of the sixth conductive layers ML6 may be disposed on the sixth insulating layer INS6 and may be connected to the sixth via VA6.

A seventh insulating layer INS7 may be disposed on the sixth insulating layer INS6 and the sixth conductive layers ML6. Each of the seventh vias VA7 may penetrate the seventh insulating layer INS7 and may be connected to the exposed sixth conductive layer ML6. Each of the seventh conductive layers ML7 may be disposed on the seventh insulating layer INS7 and may be connected to the seventh via VA7.

An eighth insulating layer INS8 may be disposed on the seventh insulating layer INS7 and the seventh conductive layers ML7. Each of the eighth vias VA8 may penetrate the eighth insulating layer INS8 and be connected to the exposed seventh conductive layer ML7. Each of the eighth conductive layers ML8 may be disposed on the eighth insulating layer INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating layers INS1 to INS8 may be formed of a silicon oxide (SiOₓ)-based inorganic layer, but embodiments are not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. For example, the thickness of the first conductive layer ML1 may be about 1360 Å. The thickness of each of the second conductive layer ML2, the third conductive layer ML3, the fourth conductive layer ML4, the fifth conductive layer ML5. The sixth conductive layer ML6 may be about 1440 Å. The thickness of each of the first via VA1, the second via VA2, the third via VA3, the fourth via VA4, the fifth via VA5, and the sixth via VA6 may be about 1,150 Å.

The thickness of each of the seventh conductive layer ML7 and the eighth conductive layer ML8 may be larger than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than the thickness of the seventh via VA7 and the thickness of the eighth via VA8, respectively. The thickness of each of the seventh via VA7 and the eighth via VA8 may be larger than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, the thickness of each of the seventh conductive layer ML7 and the eighth conductive layer ML8 may be about 9,000 Å. The thickness of each of the seventh via VA7 and the eighth via VA8 may be about 6,000 Å.

The ninth insulating layer INS9 may be disposed on the eighth insulating layer INS8 and the eighth conductive layer ML8. The ninth insulating layer INS9 may be formed of a silicon oxide (SiOₓ)-based inorganic layer, but embodiments are not limited thereto.

Each of the ninth vias VA9 may penetrate the ninth insulating layer INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be about 16,500 Å.

The display element layer EML may be disposed on the light emitting element backplane EBP. The display element layer EML may include light emitting elements LE each including a reflective electrode layer RL, tenth and eleventh insulating layers INS10 and INS11, a tenth via VA10, the first electrode AND, a light emitting stack IL, and a second electrode CAT, a pixel defining layer PDL, and trenches TRC.

The reflective electrode layer RL may be disposed on the ninth insulating layer INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7.

Each of the first reflective electrodes RL1 may be disposed on the ninth insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

The fourth reflective electrodes RL4 may be respectively disposed on the third reflective electrodes RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be about 100 Å, and the thickness of the second reflective electrode RL2 may be 850 Å.

The tenth insulating layer INS10 may be disposed on the ninth insulating layer INS9. The tenth insulating layer INS10 may be disposed between the reflective electrode layers RL adjacent to each other in a horizontal direction. The tenth insulating layer INS10 may be disposed on the reflective electrode layer RL in the third sub-pixel SP3. The tenth insulating layer INS10 may be formed of a silicon oxide (SiOₓ)-based inorganic layer, but embodiments are not limited thereto.

The eleventh insulating layer INS11 may be disposed on the tenth insulating layer INS10 and the reflective electrode layer RL. The eleventh insulating layer INS11 may be formed of a silicon oxide (SiOₓ)-based inorganic layer, but embodiments are not limited thereto. The tenth insulating layer INS10 and the eleventh insulating layer INS11 may be an optical auxiliary layer through which light reflected by the reflective electrode layer RL passes, among light emitted from the light emitting elements LE.

In order to match the resonance distance of the light emitted from the light emitting elements LE in at least one of the first sub-pixel SP1, the second sub-pixel SP2, or the third sub-pixel SP3, the tenth insulating layer INS10 and the eleventh insulating layer INS11 may not be disposed under the first electrode AND of the first sub-pixel SP1. The first electrode AND of the first sub-pixel SP1 may be disposed (e.g., directly disposed) on the reflective electrode layer RL. The eleventh insulating layer INS11 may be disposed under the first electrode AND of the second sub-pixel SP2. The tenth insulating layer INS10 and the eleventh insulating layer INS11 may be disposed under the first electrode AND of the third sub-pixel SP3.

In summary, the distance between the first electrode AND and the reflective electrode layer RL may be different in the first sub-pixel SP1, the second sub-pixel SP2, and the third sub-pixel SP3. For example, in order to adjust the distance from the reflective electrode layer RL to the second electrode CAT according to the main wavelength of the light emitted from each of the first sub-pixel SP1, the second sub-pixel SP2, and the third sub-pixel SP3, the presence or absence of the tenth insulating layer INS10 and the eleventh insulating layer INS11 may be set in each of the first sub-pixel SP1, the second sub-pixel SP2, and the third sub-pixel SP3. For example, it is illustrated in FIG. 7 that the distance between the first electrode AND and the reflective electrode layer RL in the third sub-pixel SP3 is larger than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 is larger than the distance between the first electrode AND and the reflective electrode layer RL in the first sub-pixel SP1, but embodiments are not limited thereto.

For example, although the tenth insulating layer INS10 and the eleventh insulating layer INS11 are illustrated in the embodiment, a twelfth insulating layer disposed under the first electrode AND of the first sub-pixel SP1 may be added. For example, the eleventh insulating layer INS11 and the twelfth insulating layer INS12 may be disposed under the first electrode AND of the second sub-pixel SP2, and the tenth insulating layer INS10, the eleventh insulating layer INS11, and the twelfth insulating layer INS12 may be disposed under the first electrode AND of the third sub-pixel SP3.

Each of the tenth vias VA10 may penetrate the tenth insulating layer INS10 and/or the eleventh insulating layer INS11 in the second sub-pixel SP2 and the third sub-pixel SP3 and may be connected to the exposed ninth conductive layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second sub-pixel SP2 may be smaller than the thickness of the tenth via VA10 in the third sub-pixel SP3.

The first electrode AND of each of the light emitting elements LE may be disposed on the tenth insulating layer INS10 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining layer PDL may be disposed on a part of the first electrode AND of each of the light emitting elements LE. The pixel defining layer PDL may cover the edge portion of the first electrode AND of each of the light emitting elements LE. The pixel defining layer PDL may function to partition the first emission areas EA1, the second emission areas EA2, and the third emission areas EA3.

The first emission area EA1 may be defined as an area in which the first electrode AND, the light emitting stack IL, and the second electrode CAT may be sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining layer PDL may include first to third pixel defining layers PDL1, PDL2, and PDL3. The first pixel defining layer PDL1 may be disposed on the edge portion of the first electrode AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOₓ)-based inorganic layer, but embodiments are not limited thereto. The first pixel defining layer PDL1, the second pixel defining layer PDL2, and the third pixel defining layer PDL3 may each have a thickness of about 500 Å.

In case that the first pixel defining layer PDL1, the second pixel defining layer PDL2, and the third pixel defining layer PDL3 are formed as a single pixel defining layer, the height of the single pixel defining layer may increase in a step-like manner, so that step coverage (or step-like manner) may cause a first encapsulation inorganic layer TFE1 to be cut off. Step coverage refers to the ratio of the size (or area) of a thin film coated on an inclined portion to the size (or area) of a thin film coated on a flat portion. As the step coverage decreases, the thin film is more likely to be cut off at inclined portions.

Therefore, in order to prevent the first encapsulation inorganic layer TFE1 from being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the trenches TRC may penetrate the first pixel defining layer PDL1, the second pixel defining layer PDL2, and the third pixel defining layer PDL3. Furthermore, each of the trenches TRC may penetrate the eleventh insulating layer INS11. The tenth insulating layer INS10 may be recessed (e.g., partially recessed) at each of the trenches TRC.

At least one trench TRC may be disposed between adjacent sub-pixels SP1, SP2, and SP3. Although FIG. 7 illustrates that two trenches TRC are disposed between adjacent sub-pixels SP1, SP2, and SP3, embodiments are not limited thereto.

The light emitting stack IL may include intermediate layers. FIG. 7 illustrates that the light emitting stack IL has a three-tandem structure including the first stack layer IL1, the second stack layer IL2, and the third stack layer IL3, but embodiments are not limited thereto. For example, the light emitting stack IL may have a two-tandem structure including two intermediate layers.

In the three-tandem structure, the light emitting stack IL may have a tandem structure including stack layers IL1, IL2, and IL3 that emit different lights. For example, the light emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked with each other.

The first stack layer IL1 may have a structure in which a first hole transport layer, a first organic light emitting layer that emits light of the first color, and a first electron transport layer are sequentially stacked with each other. The second stack layer IL2 may have a structure in which a second hole transport layer, a second organic light emitting layer that emits light of the third color, and a second electron transport layer are sequentially stacked with each other. The third stack layer IL3 may have a structure in which a third hole transport layer, a third organic light emitting layer that emits light of the second color, and a third electron transport layer are sequentially stacked with each other.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining layer PDL, and may be disposed on the bottom surface of each trench TRC. Due to the trench TRC, the first stack layer IL1 may be cut off between adjacent sub-pixels SP1, SP2, and SP3. The second stack layer IL2 may be disposed on the first stack layer IL1. Due to the trench TRC, the second stack layer IL2 may be cut off between adjacent sub-pixels SP1, SP2, and SP3. A cavity ESS or an empty space may be disposed between the first stack layer IL1 and the second stack layer IL2. The third stack layer IL3 may be disposed on the second stack layer IL2. The third stack layer IL3 may not be cut off by the trench TRC and may be disposed to cover the second stack layer IL2 in each of the trenches TRC. For example, in the three-tandem structure, each of the trenches TRC may be a structure for cutting off the first to second stack layers IL1 and IL2, the first charge generation layer, and the second charge generation layer of the display element layer EML between the sub-pixels SP1, SP2, and SP3 adjacent to each other. For example, in the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between adjacent sub-pixels SP1, SP2, and SP3, the height of each of the trenches TRC may be greater than the height of the pixel defining layer PDL. The height of each of the trenches TRC refers to the length of each of the trenches TRC in the third direction DR3. The height of the pixel defining layer PDL refers to the length of the pixel defining layer PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered wall (e.g., reverse tapered partition wall) may be disposed on the pixel defining layer PDL.

The number of the stack layers IL1, IL2, and IL3 that emit different lights is not limited to that shown in FIG. 7. For example, the light emitting stack IL may include two intermediate layers. For example, one of the two intermediate layers may be substantially the same as the first stack layer IL1, and the other may include a second hole transport layer, a second organic light emitting layer, a third organic light emitting layer, and a second electron transport layer. For example, a charge generation layer for supplying electrons to an intermediate layer and supplying charges to another intermediate layer may be disposed between the two intermediate layers.

FIG. 7 illustrates that the first to third stack layers IL1, IL2, and IL3 are all disposed in the first emission area EA1, the second emission area EA2, and the third emission area EA3, but embodiments are not limited thereto. For example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. For example, first to third color filters CF1, CF2, and CF3 of the optical layer OPL may be omitted.

The second electrode CAT may be disposed on the third stack layer IL3. The second electrode CAT may be disposed on the third stack layer IL3 in each of the trenches TRC. The second electrode CAT may be formed of a transparent conductive material (TCO) such as ITO or IZO that transmits light or a semi-transmissive conductive material such as magnesium (Mg), silver (Ag), or an alloy of Mg and Ag. In case that the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic layer to prevent oxygen or moisture from permeating into the display element layer EML. For example, the encapsulation layer TFE may include the first encapsulation inorganic layer TFE1, and a second encapsulation inorganic layer TFE2.

The first encapsulation inorganic layer TFE1 may be disposed on the second electrode CAT. The first encapsulation inorganic layer TFE1 may be formed as a multilayer in which one or more inorganic layers selected from silicon nitride (SiNₓ), silicon oxy nitride (SiOₓN_{y}), and silicon oxide (SiOₓ) are alternately stacked. The first encapsulation inorganic layer TFE1 may be formed by a chemical vapor deposition (CVD) process.

The second encapsulation inorganic layer TFE2 may be disposed on the first encapsulation inorganic layer TFE1. The second encapsulation inorganic layer TFE2 may be formed of titanium oxide (TiOₓ) or aluminum oxide (AlOₓ), but embodiments are not limited thereto. The second encapsulation inorganic layer TFE2 may be formed by an atomic layer deposition (ALD) process. The thickness of the second encapsulation inorganic layer TFE2 may be smaller than the thickness of the first encapsulation inorganic layer TFE1.

An organic layer APL may be a layer for increasing the interfacial adhesion between the encapsulation layer TFE and the optical layer OPL. The organic layer APL may be an organic layer such as acrylic resin, epoxy resin, phenolic resin, polyamide resin, or polyimide resin.

The optical layer OPL may include color filters CF1, CF2, and CF3, lenses LNS, and a filling layer FIL. The color filters CF1, CF2, and CF3 may include the first to third color filters CF1, CF2, and CF3. In another example, the first to third color filters CF1, CF2, and CF3 may be disposed on an adhesive layer.

The first color filter CF1 may overlap the first emission area EA1 of the first sub-pixel SP1. The first color filter CF1 may transmit light of the first color, e.g., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, e.g., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, e.g., light of a red wavelength band. The red wavelength band may be about 600 nm to about 750 nm. Thus, the third color filter CF3 may transmit light of the third color among light emitted from the third emission area EA3.

The lenses LNS may be disposed on the first color filter CF1, the second color filter CF2, and the third color filter CF3, respectively. Each of the lenses LNS may be a structure for increasing a ratio of light directed to the front of the display device 10. Each of the lenses LNS may have a cross-sectional shape that is convex in an upward direction (e.g., third direction DR3).

The filling layer FIL may be disposed on the lenses LNS. The filling layer FIL may have a selected refractive index such that light transmits in the third direction DR3 at an interface between the filling layer FIL and the lenses LNS. Further, the filling layer FIL may be a planarization layer. The filling layer FIL may be an organic layer such as acrylic resin, epoxy resin, phenolic resin, polyamide resin, or polyimide resin.

The cover layer CVL may be disposed on the filling layer FIL. The cover layer CVL may be a glass substrate or a polymer resin. In case that the cover layer CVL is a glass substrate, it may be attached onto the filling layer FIL. For example, the filling layer FIL may function to bond the cover layer CVL. In case that the cover layer CVL is a glass substrate, the cover layer CVL may function as an encapsulation substrate. In case that the cover layer CVL is a polymer resin, the cover layer CVL may be applied (e.g., directly applied) onto the filling layer FIL.

The polarizing plate POL may be disposed on a surface of the cover layer CVL. The polarizing plate POL may be a structure for preventing visibility degradation caused by reflection of external light. The polarizing plate POL may include a linear polarizing plate and a phase retardation film. For example, the phase retardation film may be a V/4 plate (quarter-wave plate), but embodiments are not limited thereto. However, in case that visibility degradation caused by reflection of external light is sufficiently overcome by the first to third color filters CF1, CF2, and CF3, the polarizing plate may be omitted.

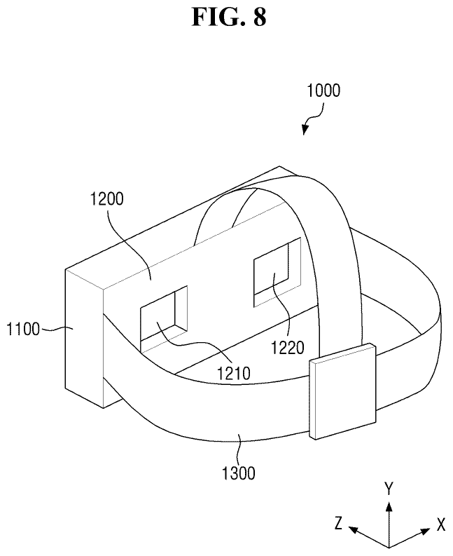

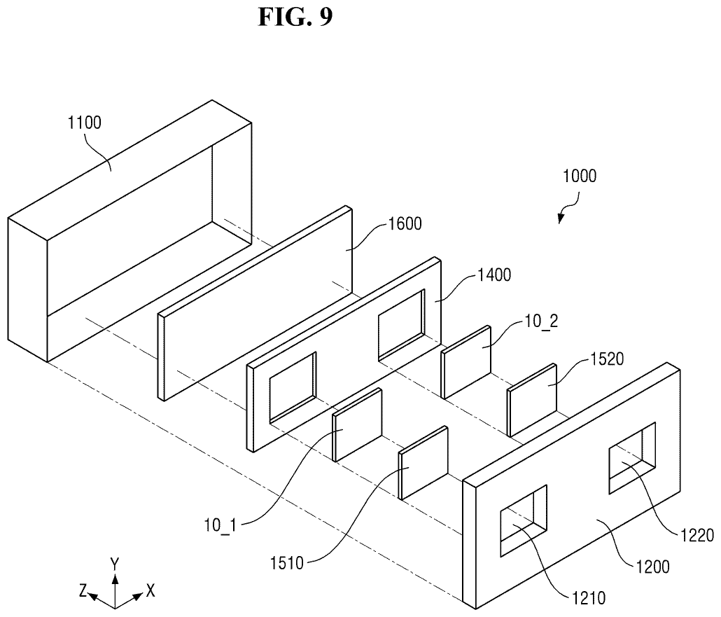

FIG. 8 is a schematic perspective view illustrating a head mounted display according to an embodiment. FIG. 9 is an exploded schematic perspective view illustrating an example of the head mounted display of FIG. 8.

Referring to FIGS. 8 and 9, a head mounted display 1000 according to an embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 may provide an image to the user's right eye. Since each of the first display device 10_1 and the second display device 10_2 is substantially the same as the display device 10 described in conjunction with FIGS. 1 and 2, a description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 may function to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. In another example, the control circuit board 1600 may transmit the same digital video data DATA to the first display device 10_1 and the second display device 10_2.

The display device housing 1100 may function to accommodate the first display device 10_1, the second display device 10_2, the middle frame 1400, the first optical member 1510, the second optical member 1520, and the control circuit board 1600. The housing cover 1200 may be disposed to cover an open surface of the display device housing 1100. The housing cover 1200 may include the first eyepiece 1210 at which the user's left eye is disposed and the second eyepiece 1220 at which the user's right eye is disposed. FIGS. 8 and 9 illustrate that the first eyepiece 1210 and the second eyepiece 1220 are disposed separately, but embodiments are not limited thereto. The first eyepiece 1210 and the second eyepiece 1220 may be combined into one (or integral with each other).

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

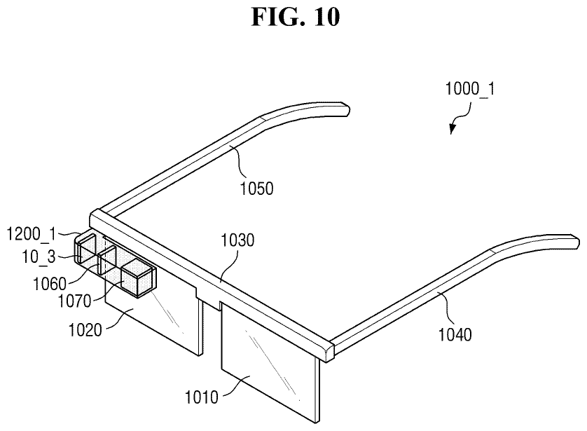

The head mounted band 1300 may function to secure the display device housing 1100 to the user's head such that the first eyepiece 1210 and the second eyepiece 1220 of the housing cover 1200 may remain disposed on the user's left and right eyes, respectively. In case that the display device housing 1200 is implemented to be lightweight and compact, the head mounted display 1000 may be provided with, as shown in FIG. 10, an eyeglass frame instead of the head mounted band 1300.

For example, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating a head mounted display 1000_1 according to an embodiment.

Referring to FIG. 10, the head mounted display 1000_1 according to an embodiment may be an eyeglasses-type display device in which a display device housing 1200_1 is implemented in a lightweight and compact manner. The head mounted display 1000_1 according to an embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end portion of the support frame 1030, but embodiments are not limited thereto. For example, the display device housing 1200_1 may be disposed at the left end portion of the support frame 1030, and the image of the display device 10_3 may be provided to the user's left eye. In another example, the display device housing 1200_1 may be disposed at both the left and right end portions of the support frame 1030, and the user may view the image displayed on the display device 10_3 through both the left and right eyes.

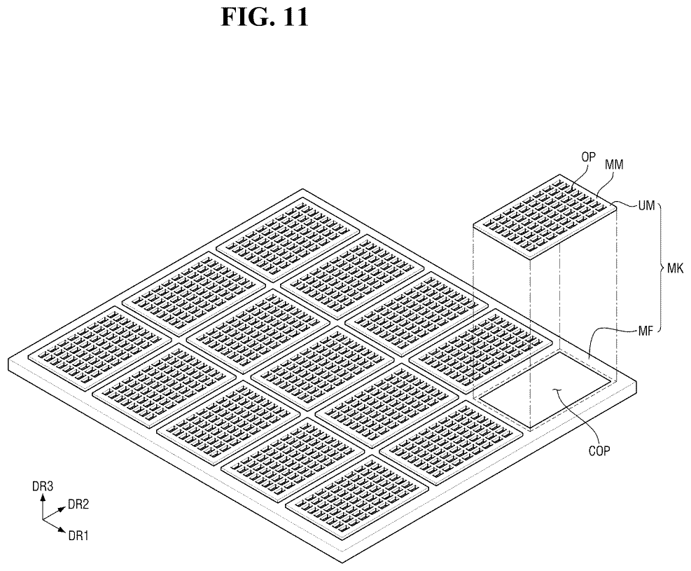

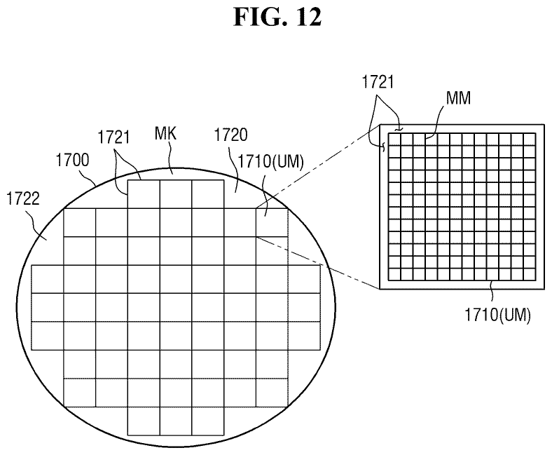

FIG. 11 is a schematic perspective view of a mask MK (or a deposition mask) according to an embodiment. FIG. 12 is a schematic plan view of the mask MK according to an embodiment. FIG. 11 is a schematic perspective view illustrating a state in which a unit mask UM is separated from unit masks. The mask MK according to the embodiment illustrated in FIGS. 11 and 12 may be used in a process of depositing at least a portion of the light emitting stack IL described with reference to FIG. 7. For example, the light emitting stack IL may emit light of different colors in the sub-pixels SP1 through SP3.

Referring to FIGS. 11 and 12, the mask MK according to an embodiment may be a shadow mask in which mask membranes MM are disposed on a silicon substrate 1700. The mask MK according to the embodiment may be referred to as a “silicon mask.”

According to an embodiment, the mask MK may include the silicon substrate 1700, and the mask membranes MM may be disposed on the silicon substrate 1700. The mask membranes MM may be respectively disposed in cell areas 1710 arranged in a matrix form, and each cell area 1710 may be surrounded by a mask rib area 1721. A portion of the silicon substrate 1700 may be disposed in the mask rib area 1721. The mask rib area 1721 may support the mask membranes MM.

A mask membrane MM may be a part of a unit mask UM disposed in each of the cell areas 1710.

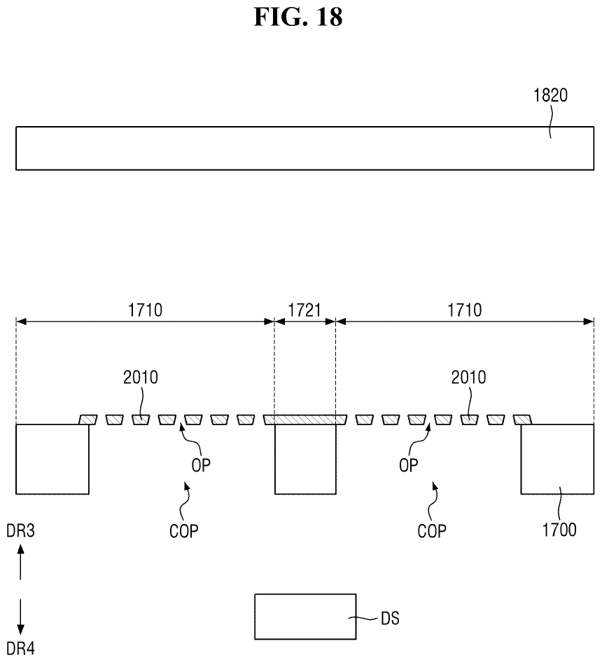

The silicon substrate 1700 may include cell areas 1710 and a mask frame area 1720 excluding (or defining) the cell areas 1710. The mask frame area 1720 may include the mask rib area 1721 surrounding each cell area 1710 and an outer frame area 1722 disposed at an outermost periphery of the silicon substrate 1700. A mask frame MF may be disposed in the mask frame area 1720. The mask frame MF may include mask ribs 7211 (see FIG. 18) surrounding the cell areas 1710.

The mask rib area 1721 may be an area that separates the cell areas 1710. For example, the cell areas 1710 may be arranged in a matrix form, and the mask ribs 7211 (see FIG. 18) disposed in the mask rib area 1721 may surround the outside of the mask membrane MM disposed in each of the cell areas 1710.

A cell opening COP and a unit mask UM, which masks at least a portion of the cell opening COP, may be disposed in each of the cell areas 1710 of the silicon substrate 1700.

Cell openings COP may penetrate the mask frame MF along the thickness direction (e.g., the third direction DR3) of the mask MK. The cell openings COP may be formed by etching (e.g., partially etching) the silicon substrate 1700 from a back side.

Each unit mask UM may include a mask membrane MM, and the mask membrane MM may include mask openings.

The mask openings of each mask membrane MM may be referred to as “holes” or “mask holes”. The mask openings may penetrate the unit masks UM along the thickness direction (e.g., the third direction DR3) of the mask MK.

A unit mask UM may be used in a deposition process of a display panel 100. In the disclosure, the term “unit mask UM” may be replaced with a term such as “mask unit UM”.

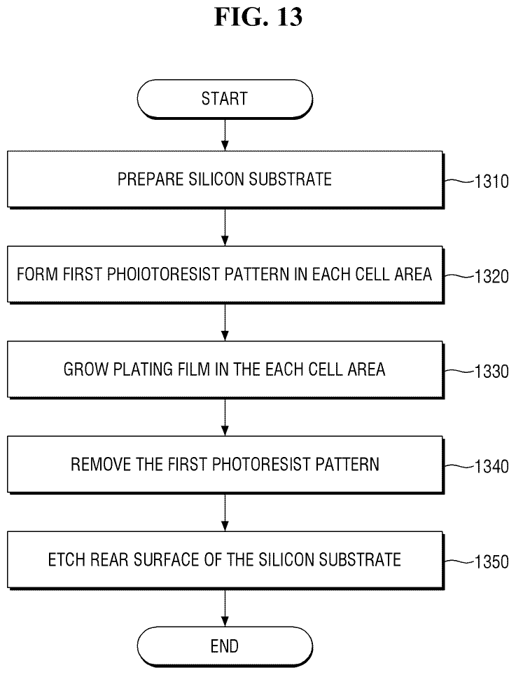

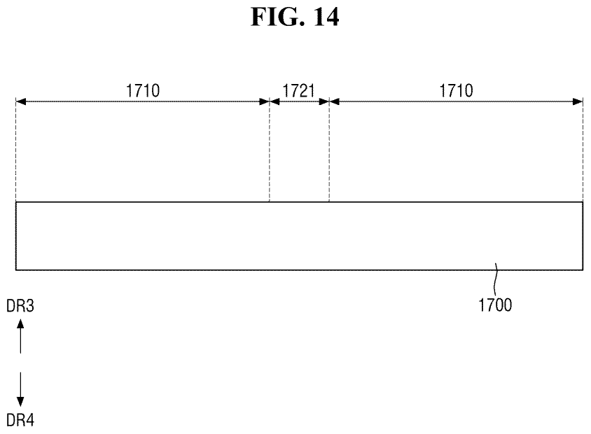

FIG. 13 is a flowchart for illustrating a method of manufacturing a mask according to an embodiment. FIGS. 14 to 18 are schematic cross-sectional views for illustrating processing steps of the method of manufacturing a mask according to an embodiment.

Hereinafter, with reference to FIGS. 13 to 18, a method of fabricating a mask according to an embodiment will be described. It should be noted that only some of fabrication processes of the mask will be described. Other processes for forming the elements described herein may be additionally performed before or after the fabrication processes described below. For example, fabrication processes of masks known in the art may be additionally performed before or after the fabrication processes described below.

Referring to FIGS. 13 and 14, in a step 1310, a silicon substrate 1700 may be prepared. The silicon substrate 1700 may function as a base substrate of a mask MK. For example, the silicon substrate 1700 may be formed as a base substrate of the mask MK, but embodiments are not limited thereto. For example, the mask MK may use a substrate including materials other than silicon as a base substrate.

According to an embodiment, the base substrate (e.g., a second substrate or the silicon substrate 1700) of the mask MK may be designed as the following to facilitate forming a mask membrane MM of high resolution of about 3500 PPI or more on the top portion of the base substrate.

According to an embodiment, the thermal expansion coefficient (CTE) of the base substrate (e.g., the second substrate or the silicon substrate 1700) of the mask MK may differ by less than about 5% from the thermal expansion coefficient of a target substrate (e.g., a first substrate, the semiconductor substrate SSUB, or the semiconductor backplane SBP) of the panel 100 (see FIG. 1).

According to an embodiment, the surface of the base substrate (e.g., the second substrate or the silicon substrate 1700) of the mask MK may have a roughness less than or equal to about 20 nm.

According to an embodiment, the base substrate (e.g., the second substrate or the silicon substrate 1700) of the mask MK may be a substrate having a total thickness variation parameter (TTV) less than or equal to about 100 μm.

According to an embodiment, the base substrate (e.g., the second substrate or the silicon substrate 1700) of the mask MK may be a substrate having a first bending parameter (BOW), which indicates the degree of bending and is less than or equal to about 100 μm.

According to an embodiment, the base substrate (e.g., the second substrate or the silicon substrate 1700) of the mask MK may be a substrate having a distortion parameter (WARP), which indicates a degree of distortion and is less than or equal to about 100 μm.

According to an embodiment, the base substrate (e.g., the second substrate or the silicon substrate 1700) of the mask MK may be a substrate having a second bending parameter (warpage), which indicates the degree of bending and is less than or equal to about 100 μm.

According to an embodiment, the base substrate (e.g., the second substrate or the silicon substrate 1700) of the mask MK may be a substrate having a volume resistance of less than or equal to about 10,000 Ohm*cm due to impurity doping.

Hereinafter, for convenience of explanation, the base substrate of the mask MK will be described as the silicon substrate 1700, but embodiments are not limited thereto.

The silicon substrate 1700 may be defined to be divided into cell areas 1710 and a mask frame area 1720 excluding (or defining) the cell areas 1710. The mask frame area 1720 may include a mask rib area 1721 surrounding the outer edge portion of the cell areas 1710.

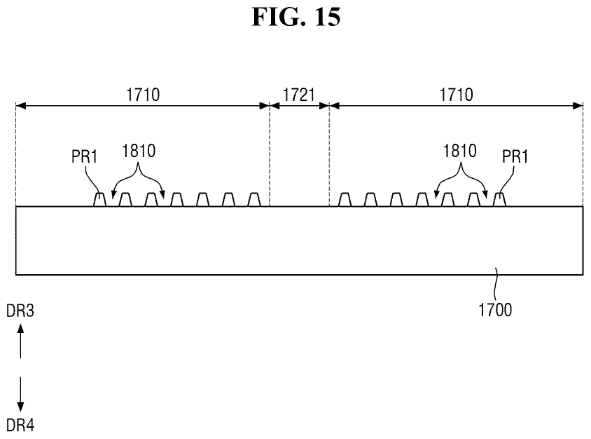

Referring to FIGS. 13 and 15, in a step 1320, a first photoresist pattern PR1 may be formed in each cell area 1710. The first photoresist pattern PR1 may be formed by applying a photoresist composition on the silicon substrate 1700 and patterning the photoresist composition. This first photoresist pattern PR1 may be disposed in each cell area 1710 and may include first openings 1810. The first openings 1810 of the first photoresist pattern PR1 may expose the front surface of the silicon substrate 1700 during the process.

For example, a seed metal layer may be disposed on the silicon substrate 1700, and the first photoresist pattern PR1 may be disposed on the seed metal layer.

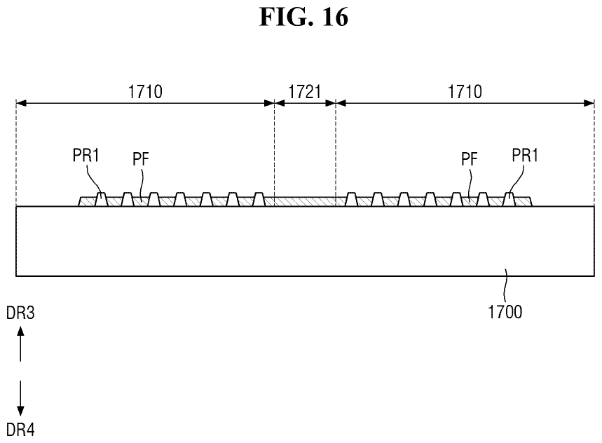

The seed metal layer may function as a seed and a barrier metal to prevent a plating film PF (see FIG. 16) from penetrating into the silicon substrate 1700 in case of performing electroplating. The seed metal layer may be a single layer or a multilayer made of one or more conductive metal of titanium (Ti), titanium nitride (TiN), tantalum (Ta), tantalum nitride (TaN), nickel (Ni), gold (Au), and molybdenum (Mo).

Referring to FIGS. 13 and 16, in a step 1330, the plating film PF may be grown in each cell area 1710. The plating film PF may grow in the first openings 1810 of the first photoresist pattern PR1. A portion of the plating film PF may be disposed to be connected to the mask rib 7211 surrounding the outside of each cell area 1710. An embodiment is not limited to the plating film PF being connected to the mask rib 7211 at the outside of each cell area 1710. For example, the plating film PF and the mask rib 7211 may not be connected and may be disconnected outside of each cell area 1710.

The cross section of the first photoresist pattern PR1 disposed around the first openings 1810 may have a regular taper shape. For example, the first photoresist pattern PR1 may have a regular taper shape by patterning a positive photoresist composition. The cross section of the first photoresist pattern PR1 may have a regular taper shape so that the cross section of the plating film PF which will become a portion (e.g., mask shadow) of the mask membrane MM may have a reverse tapered shape.

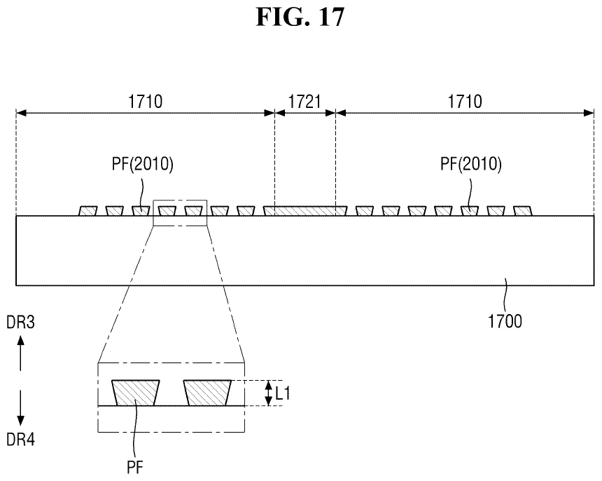

Referring to FIGS. 13 and 17, in a step 1340, the first photoresist pattern PR1 may be removed. The plating film PF which remains after the first photoresist pattern PR1 is removed may function as the mask membrane MM in each cell area 1710. A mask shadow 2010 of the mask membrane MM may be formed by the plating film PF, and the cross section of the mask shadow 2010 of the mask membrane MM may have a reverse tapered shape. The mask membrane MM may include the mask shadow 2010 formed by the plating film PF and a hole OP (see FIG. 18) disposed between adjacently disposed mask shadows 2010.

A cross section of each mask membrane MM may have a reverse tapered shape which decreases in width as being closer to the silicon substrate 1700 (or narrows as moving from a forward direction DR3 of the silicon substrate 1700 toward the backward direction DR4 of the silicon substrate 1700). A cross section of the mask opening OP may have a regular taper shape which increases in width as being closer to the silicon substrate 1700 (or widens as moving from the forward direction DR3 of the silicon substrate 1700 toward the backward direction DR4 of the silicon substrate 1700). In an embodiment, the cross section of each mask membrane MM may have a reverse tapered shape, thereby reducing shadow defects during a deposition process.

According to an embodiment, a thickness L1 of the mask membrane MM may be less than or equal to about 10 μm. The mask MK according to an embodiment may reduce shadow defects.

Referring to FIGS. 13 and 18, in a step 1350, the rear surface of the silicon substrate 1700 may be etched. For example, a second photoresist pattern may be formed on the rear surface of the silicon substrate 1700. The second photoresist pattern may include second openings for defining a cell opening COP corresponding to each of the unit masks UM. For example, each of the second openings may correspond to a single cell opening COP. Subsequently, the silicon substrate 1700 may be etched from the backward direction DR4 thereof using the second photoresist pattern. For example, the backward direction DR4 indicates the direction in which a deposition source DS is positioned. The rear surface of the mask shadow 2010 of the mask membrane MM formed of the plating film PF may be exposed by etching the silicon substrate 1700. For example, the seed metal layer deposited on the front surface of the silicon substrate 1700 before growing the plating film PF may function as an etch stopper in case of etching the silicon substrate 1700 from the rear surface. For example, the deposition source DS may inject a deposition material toward the mask MK such that the deposition material may be deposited on the first substrate 1820 through the hole OP and the cell opening COP.

The mask membrane MM according to an embodiment may have the following characteristics as it is manufactured on the silicon substrate 1700 as described in a step 1310. For example, the characteristics of the mask membrane MM described below may be the result of the thermal expansion coefficient, a roughness parameter, a total thickness variation parameter (TTV), a first bending parameter (BOW), a distortion parameter (WARP), a second bending parameter (warpage), and volume resistance of the silicon substrate 1700 described in a step 1310 meeting specified conditions.

According to an embodiment, the pixel pitch of the mask membrane MM may be less than or equal to about 7.2 μm.

According to an embodiment, the diameter of each hole OP included in the mask membrane MM may be less than or equal to about 5 μm.

According to an embodiment, the thickness of the mask membrane MM may be less than or equal to about 10 μm.

According to an embodiment, the critical dimension uniformity between the holes OP included in the mask membrane MM may be less than or equal to about 0.5 μm.

According to an embodiment, the pixel position accuracy (PPA) of the holes OP included in the mask membrane MM may be less than or equal to about 0.5 μm.

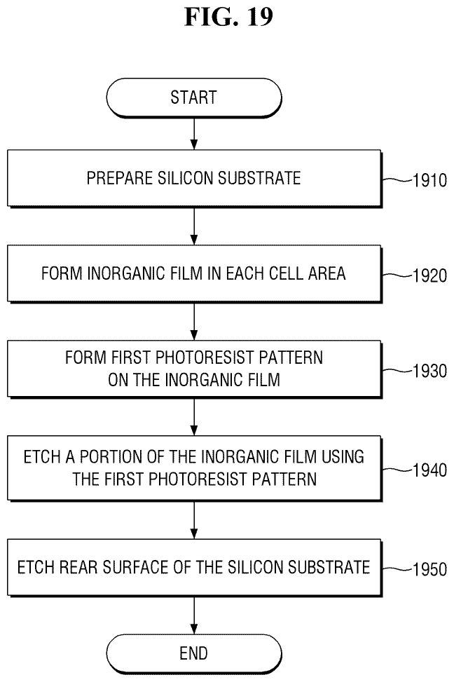

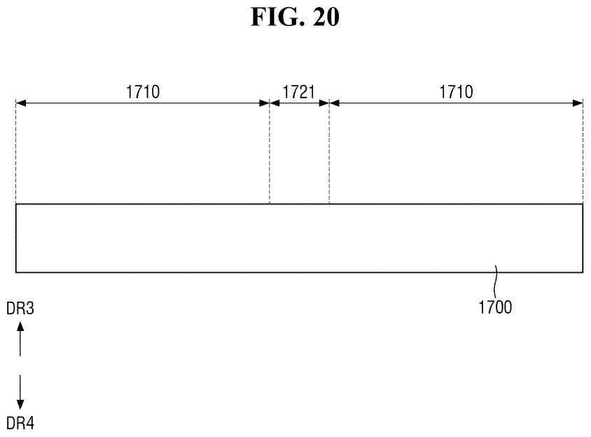

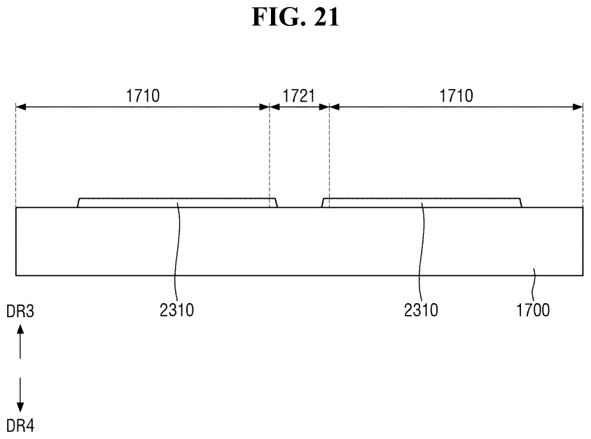

FIG. 19 is a flowchart for illustrating a method of manufacturing a mask according to an embodiment. FIGS. 20 to 24 are schematic cross-sectional views for illustrating processing steps of the method of manufacturing a mask according to an embodiment.

The embodiments of FIGS. 19 to 24 are different from the embodiments of FIGS. 13 to 19 in that the mask membrane MM is formed of an inorganic film.

Referring to FIGS. 19 and 20, in a step 1910, a silicon substrate 1700 may be prepared. The silicon substrate 1700 may function as a base substrate of a mask MK. For example, the silicon substrate 1700 may be formed as a base substrate of the mask MK, but embodiments are not limited thereto. For example, the mask MK may use a substrate including materials other than silicon as a base substrate.

According to an embodiment, the base substrate (e.g., a second substrate or the silicon substrate 1700) of the mask MK may be designed as the following to facilitate forming a mask membrane MM of high resolution of about 3500 PPI or more on the top portion of the base substrate.

According to an embodiment, the thermal expansion coefficient (CTE) of the base substrate (e.g., the second substrate or the silicon substrate 1700) of the mask MK may differ by less than about 5% from the thermal expansion of the target substrate (e.g., the first substrate, the semiconductor substrate SSUB, or the semiconductor backplane SBP) of the display panel 100 (see FIG. 1).

According to an embodiment, the surface of the base substrate (e.g., the second substrate or the silicon substrate 1700) of the mask MK may have a roughness (or roughness parameter) less than or equal to about 20 nm.

According to an embodiment, the base substrate (e.g., the second substrate or the silicon substrate 1700) of the mask MK may be a substrate having a total thickness variation parameter (TTV) less than or equal to about 100 μm.

According to an embodiment, the base substrate (e.g., the second substrate or the silicon substrate 1700) of the mask MK may be a substrate in which a first bending parameter (BOW), which is a parameter indicating the degree of bending and less than or equal to about 100 μm.

According to an embodiment, the base substrate (e.g., the second substrate or the silicon substrate 1700) of the mask MK may be a substrate in which a distortion parameter (WARP), which is a parameter indicating a degree of distortion and less than or equal to about 100 μm.

According to an embodiment, the base substrate (e.g., the second substrate or the silicon substrate 1700) of the mask MK may be a substrate in which a second bending parameter (warpage), which is a parameter indicating the degree of bending and is less than or equal to about 100 μm.

According to an embodiment, the base substrate (e.g., the second substrate or the silicon substrate 1700) of the mask MK may be a substrate having a volume resistance of less than or equal to about 10,000 Ohm*cm due to impurity doping.

Hereinafter, for convenience of explanation, the base substrate of the mask MK will be described as the silicon substrate 1700, but embodiments are not limited thereto.

The silicon substrate 1700 may be defined to be divided into cell areas 1710 and a mask frame area 1720 excluding (or defining) the cell areas 1710. The mask frame area 1720 may include a mask rib area 1721 surrounding the outer edge portion of the cell areas 1710.

Step 1910 may be substantially the same or similar to step 1310 described with reference to FIG. 13.

Referring to FIGS. 19 and 20, in a step 1920, an inorganic film 2310 may be formed on each cell area 1710. The inorganic film 2310 may be deposited in each cell area 1710. The inorganic film 2310 may include a silicon-based material. For example, the inorganic film 2310 pattern may include at least one selected from silicon (Si), silicon nitride (SiNₓ), silicon oxynitride (SiOₓN_{y}), silicon oxide (SiOₓ), titanium oxide (TiOₓ), amorphous silicon (a-Si), and aluminum oxide (AlOₓ).

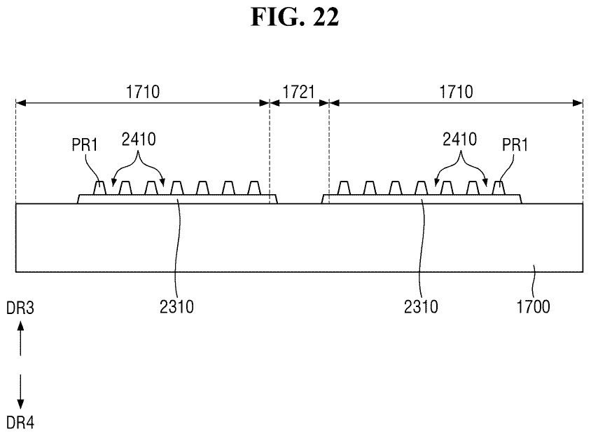

Referring to FIGS. 19 and 22, in a step 1930, a first photoresist pattern PR1 may be formed on the inorganic film 2310. The first photoresist pattern PR1 may be formed by applying a photoresist composition on the inorganic film 2310 and patterning the photoresist composition. This first photoresist pattern PR1 may be disposed on the inorganic film 2310 in each cell area 1710 and may include first openings 2410. The first openings 2410 of the first photoresist pattern PR1 may expose the front surface of the inorganic film 2310 during the process.

The cross section of the first photoresist pattern PR1 may have a regular taper shape. For example, the first photoresist pattern PR1 may have a regular taper shape by patterning a positive photoresist composition. The cross section of the first photoresist pattern PR1 may have a regular taper shape so that the cross section of the mask membrane MM may have a reverse tapered shape.

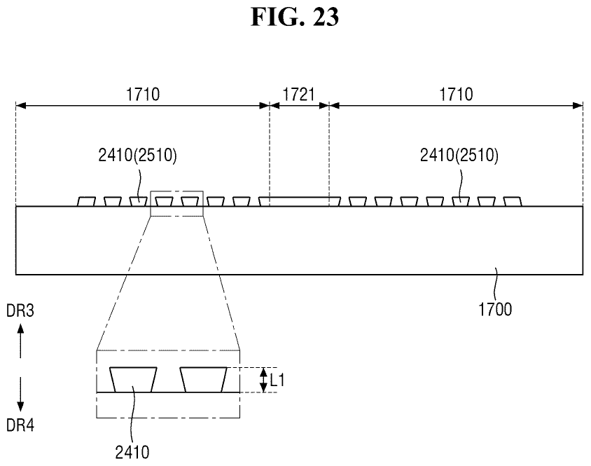

Referring to FIGS. 19 and 23, in a step 1940, a portion of the inorganic film 2310 may be etched by using the first photoresist pattern PR1. In a step 1950, the inorganic film 2310 may be etched in first openings 2410 of the first photoresist pattern PR1. After etching the inorganic film 2310, the first photoresist pattern PR1 may be removed. A portion of the inorganic film 2310 which remains after removing the first photoresist pattern PR1 may be referred to as “inorganic film pattern.” The inorganic film pattern which remains after the etching process using the first photoresist pattern PR1 may become a mask shadow 2510 of the mask membrane MM.

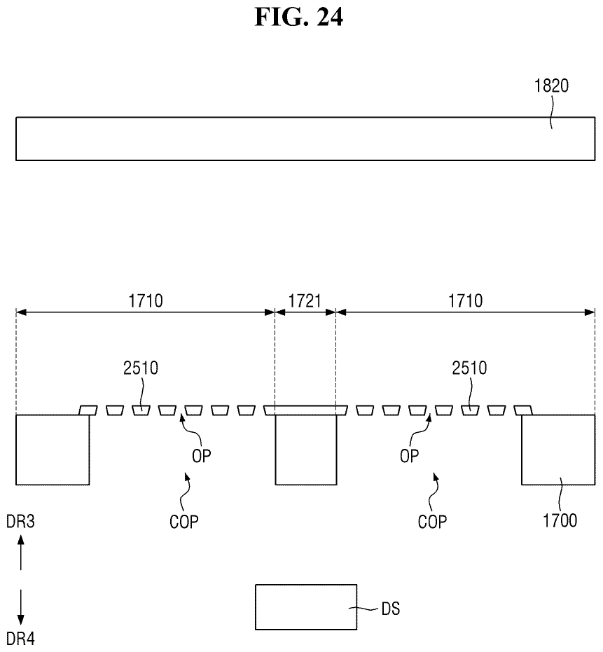

The mask shadow 2510 of the mask membrane MM may be formed of the inorganic film 2310, and the cross section of the mask shadow 2010 of the mask membrane MM may have a reverse tapered shape. The mask membrane MM may include the mask shadow 2010 formed by the inorganic film 2310 and a hole OP (see FIG. 24) disposed between adjacently disposed mask shadow 2510.

According to an embodiment, the thickness L1 of the mask membrane MM may be less than or equal to about 10 μm. The mask MK according to the embodiment may reduce shadow defects.

Referring to FIGS. 19 and 24, in a step 1950, the rear surface of the silicon substrate 1700 may be etched. For example, a second photoresist pattern may be formed on the rear surface of the silicon substrate 1700. The second photoresist pattern may include second openings for defining a cell opening COP corresponding to each of the unit masks UM. For example, each of the second openings may correspond to a single cell opening COP. Subsequently, the silicon substrate 1700 may be etched from the backward direction DR4 thereof using the second photoresist pattern. For example, the backward direction DR4 indicates the direction in which a deposition source DS is positioned. For example, the deposition source DS may inject a deposition material toward the mask MK such that the deposition material may be deposited on the first substrate 1820 through the hole OP and the cell opening COP.

The mask membrane MM according to an embodiment may have the following characteristics as it is manufactured on the silicon substrate 1700 as described in a step 1910. For example, the characteristics of the mask membrane MM described below may be the result of the thermal expansion coefficient, a roughness parameter, a total thickness variation parameter (TTV), a first bending parameter (BOW), a distortion parameter (WARP), a second bending parameter (warpage), and volume resistance of the silicon substrate 1700 described in a step 1910 meeting specified conditions.

According to an embodiment, the pixel pitch of the mask membrane MM may be less than or equal to about 7.2 μm.

According to an embodiment, the diameter of each hole OP included in the mask membrane MM may be less than or equal to about 5 μm.

According to an embodiment, the thickness of the mask membrane MM may be less than or equal to about 10 μm.

According to an embodiment, the critical dimension uniformity between the holes OP included in the mask membrane MM may be less than or equal to about 0.5 μm.

According to an embodiment, the pixel position accuracy (PPA) of the holes OP included in the mask membrane MM may be less than or equal to about 0.5 μm.

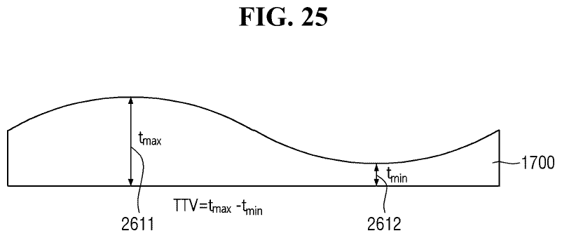

FIG. 25 is a drawing for illustrating total thickness variation which is a total thickness variation parameter (TTV).

Referring to FIG. 25, the total thickness variation parameter (TTV) may indicate the roughness and unevenness of the front surface of the base substrate, for example, a silicon substrate.

The total thickness variation parameter (TTV) may be, for example, a parameter that measures the thickness at five or more different positions of the silicon substrate 1700 and is determined based on the measured thicknesses. For example, the total thickness variation parameter (TTV) may be a parameter that indicates the difference between a maximum thickness 2611 (or tₘₐₓ) and a minimum thickness 2612 (or tₘᵢₙ) among the thicknesses measured at five or more different positions on the silicon substrate 1700. Therefore, it may be interpreted that the larger the total thickness variation parameter (TTV), the greater the roughness and unevenness of the front surface of the silicon substrate.

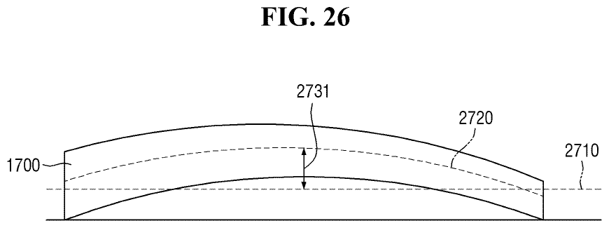

FIG. 26 is a drawing for illustrating a first bending parameter (BOW) which is a parameter indicating the degree of bending.

Referring to FIG. 26, the first bending parameter (BOW) may be a parameter indicating a maximum deviation 2731 between a reference plane 2710 and a median surface 2720 placed on a line connecting three or more different positions of the silicon substrate 1700. Therefore, it may be interpreted that the smaller the first bending parameter (BOW), the less the silicon substrate 1700 is bent.

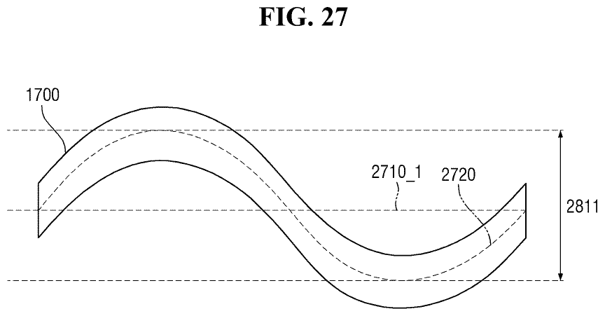

FIG. 27 is a drawing for illustrating a distortion parameter (WARP) indicating a degree of distortion.

Referring to FIG. 27, the distortion parameter (WARP) may be a parameter indicating a difference between the corrected reference plane 2710_1 and the median surface 2720 based on a first bending parameter (BOW). For example, the distortion parameter (WARP) may correspond to a variation distance 2811. Similarly to the first bending parameter (BOW), such distortion parameter (WARP) may be interpreted that the lesser the value thereof, the less the silicon substrate 1700 may be distorted.

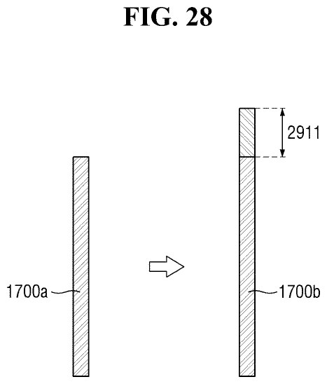

FIG. 28 is a drawing for illustrating a thermal expansion coefficient (CTE).

Referring to FIG. 28, in case that the temperature of a material increases, the average distance between the constituent particles constituting thereof may increase and the volume may increase, which is called “thermal expansion.” The thermal expansion coefficient of a solid indicates how much the solid expands for each 1K increase in temperature.

The thermal expansion coefficient described in the disclosure may be defined as the rate at which a material expands due to heat, converted to per unit temperature. For example, the silicon substrate 1700 may be in a first state 1700a having a first length before being heated in the deposition equipment. The silicon substrate 1700 may be in a second state 1700b having a second length longer than the first length after being heated in the deposition equipment. The thermal expansion coefficient of the silicon substrate 1700 may be considered to correspond to the difference 2911 between the first length and the second length.

Likewise, the length of the target substrate (e.g., the first substrate, the semiconductor substrate SSUB, or the semiconductor backplane SBP) of the display panel 100 disposed to face the silicon substrate 1700 in the deposition equipment may increase by heating, and the increased length may be determined based on a thermal expansion coefficient of the display panel 100.

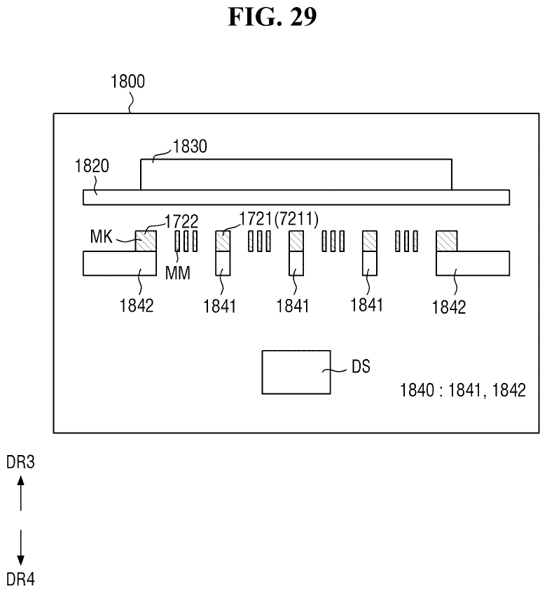

FIG. 29 is a schematic view showing a configuration of a deposition equipment according to an embodiment.

Referring to FIG. 29, the deposition equipment according to an embodiment may include a chamber 1800, a deposition source DS disposed in the chamber 1800, a mask MK disposed between a first substrate 1820 and the deposition source DS inside the chamber 1800, and a mask support 1840 disposed between the deposition source DS and the mask MK to support at least a portion of the mask MK.

According to an embodiment, the mask MK may include a second substrate 1700 including cell areas 1710 and a mask frame area 1720 excluding (or defining) the cell areas 1710, and a mask membrane MM disposed at each cell area 1710.

The first substrate 1820 shown in FIG. 29 may be a display panel 100 described with reference to FIGS. 1 to 10. Accordingly, the description in relation to the first substrate 1820 will be replaced with description of the display panel 100 with reference to FIGS. 1 to 10.

A second substrate 1700 shown in FIG. 29 may be the silicon substrate 1700 described with reference to FIGS. 11 to 28. Accordingly, the description of the second substrate 1700 will be replaced with the description of the silicon substrate 1700 with reference to FIGS. 11 to 28.

The mask support 1840 may function to support and secure the mask MK at the bottom of the mask MK. For example, the mask support 1840 may be comprised of an electrostatic chuck. According to an embodiment, the mask support 1840 may include a first support area 1841 supporting a mask rib area 1721, and a second support area 1842 supporting an outer frame area 1722. However, the mask support 1840 may not support the mask rib area 1721, and for example, the first support area 1841 may be omitted.

A fixing member 1830 shown in FIG. 29 may fix the first substrate 1820, and for example, may be configured as an electrostatic chuck.

As shown in FIG. 29, a method of manufacturing the display device 10 using a deposition equipment according to an embodiment may include the following steps. For example, the method of manufacturing the display device 10 according to an embodiment may include forming a first substrate 1820 (e.g., the display panel 100 of FIGS. 1 to 10) on a surface of a mask MK inside a chamber 1800 of a deposition equipment, arranging a deposition source DS to face another side of the first substrate 1820, vaporizing a deposition material contained in the deposition source DS such that the vaporized deposition material may pass through a mask MK to be deposited on the first substrate 1820. For example, the mask MK may be the mask MK described with reference to FIGS. 11 to 28.

In concluding the detailed description, those skilled in the art will appreciate that many variations and modifications may be made to the embodiments without substantially departing from the principles of the invention. Therefore, the disclosed embodiments are used in a generic and descriptive sense only and not for purposes of limitation.

What is claimed is:

1. A deposition mask for depositing an organic material on a first substrate, the deposition mask comprising:
a second substrate including a plurality of cell areas and a mask frame area defining the plurality of cell areas; and
a mask membrane disposed each cell area of the second substrate,
wherein a thermal expansion coefficient of the second substrate differs by less than about 5% from a thermal expansion coefficient of the first substrate.

2. The deposition mask of claim 1, wherein a surface of the second substrate has a roughness parameter in a range of about 20 nm or less.

3. The deposition mask of claim 1, wherein the second substrate is a substrate having a total thickness variation parameter in a range of about 100 μm or less.

4. The deposition mask of claim 1, wherein the second substrate is a substrate having a first bending parameter which indicates a degree of bending and is in a range of about 100 μm or less.

5. The deposition mask of claim 1, wherein the second substrate is a substrate having a distortion parameter which indicates a degree of distortion and is in a range of about 100 μm or less.

6. The deposition mask of claim 1, wherein the second substrate is a substrate having a second bending parameter which indicates a degree of bending and is in a range of about 100 μm or less.

7. The deposition mask of claim 1, wherein the second substrate is a substrate having a volume resistance in a range of about 10,000 Ohm*cm or less due to impurity doping.

8. The deposition mask of claim 1, wherein the second substrate is a silicon substrate.

9. The deposition mask of claim 1, wherein a pixel pitch of the mask membrane is in a range of about 7.2 μm or less.

10. The deposition mask of claim 1, wherein a diameter of each hole included in the mask membrane is in a range of about 5 μm or less.

11. The deposition mask of claim 1, wherein a thickness of the mask membrane is in a range of about 10 μm or less.

12. The deposition mask of claim 1, wherein a critical dimension uniformity between holes included the mask membrane is in a range of about 0.5 μm or less.

13. The deposition mask of claim 1, wherein a pixel position accuracy of holes included in the mask membrane is in a range of about 0.5 μm or less.

14. A deposition equipment comprising:
a chamber;
a deposition source disposed in the chamber; and
a mask disposed between a first substrate and the deposition source in the chamber,
wherein the mask comprises:
a second substrate comprising a plurality of cell areas and a mask frame defining the plurality of cell areas; and
a mask membrane disposed on each cell area of the second substrate, and
a thermal expansion coefficient of the second substrate differs by less than about 5% from a thermal expansion coefficient of the first substrate.

15. The deposition equipment of claim 14, wherein a surface of the second substrate has a roughness parameter in a range of about 20 nm or less.

16. The deposition equipment of claim 14, wherein the second substrate is a substrate having a total thickness variation parameter in a range of about 100 μm or less.

17. The deposition equipment of claim 14, wherein the second substrate is a substrate having a first bending parameter which indicates a degree of bending and is less than or equal to in a range of about 100 μm or less.

18. The deposition equipment of claim 14, wherein the second substrate is a substrate having a distortion parameter, which indicates a degree of distortion and is in a range of about 100 μm or less.

19. The deposition equipment of claim 14, wherein the second substrate is a substrate having a second bending parameter which indicates a degree of bending and is in a range of about 100 μm or less.

20. The deposition equipment of claim 14, wherein the second substrate is a substrate having a volume resistance in a range of about 10,000 Ohm*cm or less due to impurity doping.

21. A method of manufacturing a display device, the method comprising:
disposing a first substrate on a surface of a mask in a chamber of a deposition equipment;
disposing a deposition source to face another surface of the first substrate; and
vaporizing a deposition material contained in the deposition source such that the vaporized deposition material passes through the mask to be deposited to the first substrate,
wherein the mask comprises:
a second substrate including a plurality of cell areas and a mask frame area defining the plurality of cell areas; and
a mask membrane disposed on each cell area of the second substrate, and
a thermal expansion coefficient of the second substrate differs by less than about 5% from a thermal expansion coefficient of the first substrate.

22. The method of claim 21, wherein the surface of the second substrate has a roughness parameter in a range of about 20 nm or less.

23. The method of claim 21, wherein the second substrate is a substrate having a total thickness variation parameter in a range of about 100 μm or less.

24. The method of claim 21, wherein the second substrate is a substrate having a first bending parameter which indicates a degree of bending and is in a range of about 100 μm or less.
